(19) United States
(12) Patent Application Publication
(10) Pub. No.: US 2012/0095718 A1
(43) Pub. Date: Apr. 19, 2012

(54) AUTOMATIC TESTING SYSTEM AND METHOD

(75) Inventors: Lan Zhang, Dongguan City (CN); Wai-Hung Sum, Dongguan City (CN)

(73) Assignee: DELTA ELECTRONICS, INC., Taoyuan Hsien (TW)

(21) Appl. No.: 13/078,116

(22) Filed: Apr. 1, 2011

(30) Foreign Application Priority Data
Oct. 18, 2010 (CN) 201010515571.0

(51) Int. Cl. G06F 19/00; G01R 31/00

(52) U.S. Cl. 702/119

(57) ABSTRACT

An automatic testing system includes an equipment group and an electronic device. The equipment group includes plural equipments. The electronic device includes an input unit, a storage unit, a controller, an output unit and an integrated transmission interface. The input unit is used for inputting an instruction. The controller is electrically connected with the input unit and the storage unit for accessing the storage unit according to the instruction, thereby controlling and activating an automatic testing process and issuing a test command. The output unit is connected with the controller. The interface has a first terminal connected with the controller and a second terminal connected with the equipment group for integrating and transmitting the test command to at least one of the equipments of the equipment group, thereby allowing the equipment to perform the automatic testing process.

### FIELD OF THE INVENTION

The present invention relates to an automatic testing system and an automatic testing method, and more particularly to an automatic collaborative testing system and an automatic collaborative testing method.

### BACKGROUND OF THE INVENTION

Recently, power supply becomes essential to most electronic product. For assuring good quality of the power supply, a large number of testing and verifying procedures are necessary during the designing stage and the fabricating stage.

With increasing development of electronic products, the functions and the components of the power supply become more diversified. Correspondingly, more items need to be tested and verified. The current method for testing the power supply uses different test equipments to test various items according to different parameters. Generally, the current testing method is semi-automatic because the test results obtained from different test equipments are manually inputted into a computer for collection and comparison. Moreover, the paths of some test equipments need to be manually switched. Due to the above reasons, the conventional testing method is inefficient.

In the conventional testing system, the test items are usually insufficient. Moreover, when compared with the new testing machines, the expansibility of the hardware components of the old testing machines is low, the independence of the software used in the old testing machines is insufficient and the precision of the measuring results of the old testing machines is usually unsatisfied. For these reasons, some testing tasks need to be manually done in different testing machines. After related testing tasks are performed, the test results are manually collected or transformed into related statistical table, and further processed into a systematic test report. The test report is then stored or provided to the customer for verification. In other words, the conventional testing method is time-consuming, labor-intensive and inefficient.

Therefore, there is a need of providing automatic, precise, cost-effective, efficient and collaborative testing system and method.

### SUMMARY OF THE INVENTION

The present invention provides an automatic testing system and an automatic testing method, in which an electronic device and an equipment group collaboratively communicate with each other and the equipment group is controlled by the electronic device to automatically test a product in a precise, cost-effective, efficient and collaborative manner.

The present invention also provides an automatic testing system and an automatic testing method, in which the test result is outputted as a test report and the test report is expressed as a test sheet or a test chart. In such way, the complicated process of manually analyzing the test data is omitted, and the efficiency of testing the product is enhanced.

In accordance with an aspect of the present invention, there is provided an automatic testing system. The automatic testing system includes an equipment group and an electronic device. The equipment group includes plural equipments. The electronic device includes an input unit, a storage unit, a controller, an output unit and an integrated transmission interface. The input unit is used for inputting an instruction. The controller is electrically connected with the input unit and the storage unit for accessing the storage unit according to the instruction, thereby controlling and activating an automatic testing process and issuing a test command. The output unit is connected with the controller. The interface has a first terminal connected with the controller and a second terminal connected with the equipment group for integrating and transmitting the test command to at least one of the equipments of the equipment group.

In accordance with another aspect of the present invention, there is provided an automatic testing method. Firstly, an automatic testing system including a system H/W configuration interface, a test condition configuration interface and a H/W control and show result interface is provided. Then, at least one of plural equipments of an equipment group is selected through the system H/W configuration interface. Then, a test condition is set through the test condition configuration interface. Then, the H/W control and show result interface is accessed optionally. Then, the parameters associated with the selected equipment are set through the H/W control and show result interface when the H/W control and show result interface is accessed. Then, a test specification interface is generated and a target specification of a to-be-tested product is set through the test specification interface when said H/W control and show result interface isn't accessed. Then, a program and function test interface is accessed, and the selected equipment is enabled to test the product according to plural setting values through the program and function test interface. Afterwards, a test report is outputted.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic functional block diagram illustrating an automatic testing system according to an embodiment of the present invention;

FIG. 2 is a flowchart illustrating an automatic testing method according to an embodiment of the present invention;

FIGS. 3-1 and 3-2 are flowcharts illustrating an efficiency testing process applied to the automatic testing method of the present invention; and

FIG. 4 is a schematic diagram illustrating a test report obtained according to the automatic testing method of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

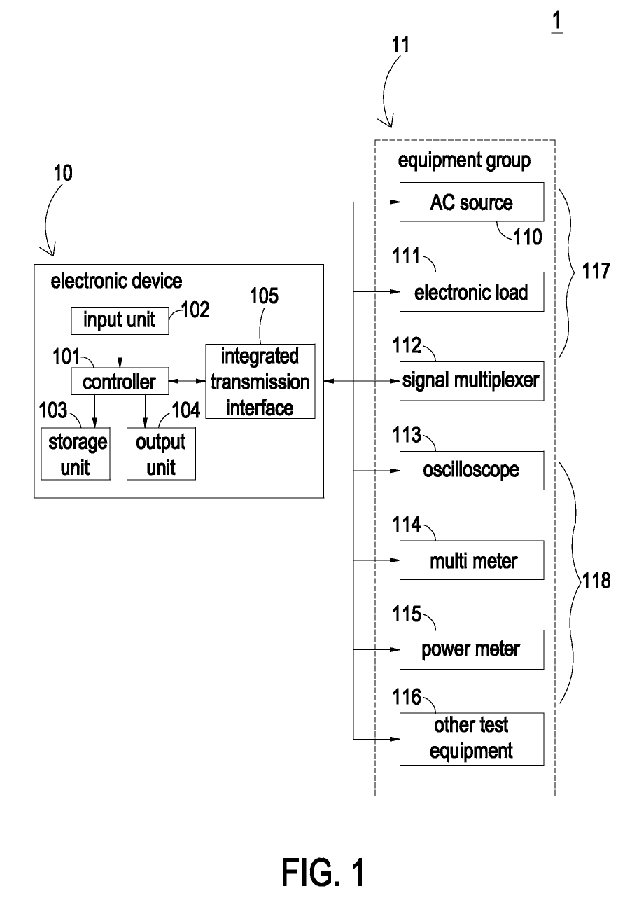

FIG. 1 is a schematic functional block diagram illustrating an automatic testing system according to an embodiment of the present invention. As shown in FIG. 1, the automatic testing system comprises an electronic device 10 and an equipment group 11. The electronic device 10 comprises a controller 101, an input unit 102, a storage unit 103, an output unit 104 and an integrated transmission interface 105. Through the input unit 102, the user can input an instruction. The controller 101 is electrically connected with the input unit 102, the storage unit 103, the output unit 104 and the integrated transmission interface 105. According to the instruction inputted into the input unit 102, the controller 101 accesses the storage unit 103 to control and activate an automatic testing process, thereby issuing a test command to the integrated transmission interface 105.

In this embodiment, the automatic testing process is performed by executing an automatic testing collaborative program, which is written in a graphic editing language (e.g. LabVIEW). The test command issued by the controller 101 of the electronic device 1 is transmitted to the plural equipments 110˜116 of the equipment group 11 through the integrated transmission interface 105. According to the test command, the devices 110˜116 are collaboratively controlled to automatically test a to-be-tested product. Since the automatic testing process written in the graphic editing language (e.g. LabVIEW) has high efficiency, high stability and high compatibility, the automatic testing system can be stably operated.

Please refer to FIG. 1 again. A first terminal of the integrated transmission interface 105 is electrically connected with the controller 101. A second terminal of the integrated transmission interface 105 is electrically connected with the equipment group 11. The integrated transmission interface 105 is used for integrating the messages of the equipment group 11 and transmitting the test command to at least one of the equipments 110˜116 of the equipment group 11, thereby performing an automatic testing process. After the automatic testing process is completed, the test result is transmitted to the controller 101 through the integrated transmission interface 105. The test result is calculated and collected by the controller 101 and transmitted to the output unit 104. Consequently, the output unit 104 will output a test report.

An example of the electronic device 10 includes but is not limited to a computer system (e.g. a personal computer system or a server system) or a PXI (PCI eXtensions for Instrumentation). The electronic device 10 is not limited to a personal electronic device, a business electronic device or any other electronic device. Since the operating interface is standardized, the electronic device 10 can be replaced with other type of electronic device. In a case that the electronic device 10 is a PXI (PCI eXtensions for Instrumentation), the utilization flexibility thereof is enhanced. According to diversified testing demands, different testing modules and the electronic device 10 can be collectively defined as different testing systems. Moreover, the flexibility of the peripheral devices is also enhanced. Through different integrated transmission interfaces (e.g. GPIB-488, RS-232, USB, Ethernet, parallel port), the electronic device 10 can communicate with the peripheral devices. As a consequence, the electronic device 10 and the current testing devices (e.g. the equipments 110˜116 of the equipment group 11) can be combined with each other to produce a more efficient and flexible automatic testing system.

In the electronic device, an example of the input unit 102 includes but is not limited to a keyboard or a mouse. An example of the controller 101 includes but is not limited to a central processing unit. An example of the storage unit 103 includes but is not limited to a memory unit or a hard disk. An example of the output unit 104 includes but is not limited to a monitor or a printing device (e.g. a printer). An example of the integrated transmission interface 105 includes but is not limited to a GPIB (general purpose interface bus) interface.

Please refer to FIG. 1 again. The equipment group 11 comprises a condition equipment sub-group 117 and a test equipment sub-group 118. The condition equipment sub-group 117 is used to provide operating conditions required for testing the product. The operating conditions include for example AC power, electronic load or alternate signals. For example, the condition equipment sub-group 117 includes an AC source 110, an electronic load 111 and a signal multiplexer 112. For example, the AC source 110 is a Chroma 6430 AC source, a Chroma AC source 6530, a Chroma 6560 AC source or a Chroma 6590 AC source. For example, the electronic load 111 is a Chroma 6304 (63030) electronic load, a Chroma 6334 (63303) electronic load, a 6334 (63306) Chroma electronic load or a Chroma 6314 (63112) electronic load. For example, the signal multiplexer 112 is a DG3 RD-TE Rev0 multiplexer, a DG3 RD-TE Rev1 multiplexer or a PXI-2527 multiplexer.

The test equipment sub-group 118 is used to detect parameters (e.g. waveform, voltage, current and power) of the product (e.g. a power supply). In this embodiment, the test equipment sub-group 118 comprises an oscilloscope 113, a multi meter (i.e. a voltage meter) 114, a power meter 115 and other test equipment 116. For example, the oscilloscope 113 is a Tektronix TDS5054 oscilloscope, a Tektronix TDS5034B oscilloscope, a Tektronix DPO7054 oscilloscope, a LeCroy LT354ML oscilloscope, a LeCroy 44Xi oscilloscope, a PXI-5105 oscilloscope or a PXI-5124 oscilloscope. For example, the multi meter 114 is an Agilent 34970A multi meter or an Agilent 34401A multi meter. For example, the power meter 115 is a Chroma 6630 power meter, a Chroma 66202 power meter, a Xitron 2801 power meter or a PXI-4071 power meter.

In such way, when at least one of the equipments 110˜116 of the equipment group 11 is used for testing a product, associated messages are exchanged between the electronic device 10 and the equipment group 11 through the integrated transmission interface 105. In addition, after associated instructions and parameters are inputted into the electronic device 10, the electronic device 10 and the equipment group 11 will collaboratively communicate with each other so that at least one of the equipments 110˜116 of the equipment group 11 is enabled to test the product. After the automatic testing process is completed, the test result is transmitted to the electronic device 10. The test result is calculated and collected by the controller 101 and then transmitted to the output unit 104, and thus the output unit 104 will output a test report.

In addition, the test report outputted from the output unit 104 can have diversified forms. For example, the test report can be expressed as a test sheet or a test chart (e.g. a waveform chart or a trend chart), which are automatically created from a text file (e.g. a Microsoft Word file) or a spreadsheet (e.g. a Microsoft Excel file). The automatically outputted test report can be inquired by the user or provided to the user for verification. Since the test report is automatically outputted, the steps of manually collecting the report will be omitted and the possible man-made erroneous events will be minimized. In other words, the efficiency of the automatic testing method is enhanced by automatically outputting the test report. Moreover, since the format of test report can be determined according to the customer's requirements, the test report is customized. In a case that high precision testing equipments of the equipment group 11 are included in the automatic testing system 1, the precision of the automatic testing method of the present invention is enhanced. Moreover, in a case that some of the precision testing equipments are cooperated with the electronic device 10 and the integrated transmission interface 105, the overall cost can be reduced. Since the equipments 110˜116 of the equipment group 11 are controlled by the electronic device 10 and the integrated transmission interface 105, it is not necessary to purchase an additional testing instrument. In such way, the automatic testing system 1 is easy-to-use, stable and cost-effective.

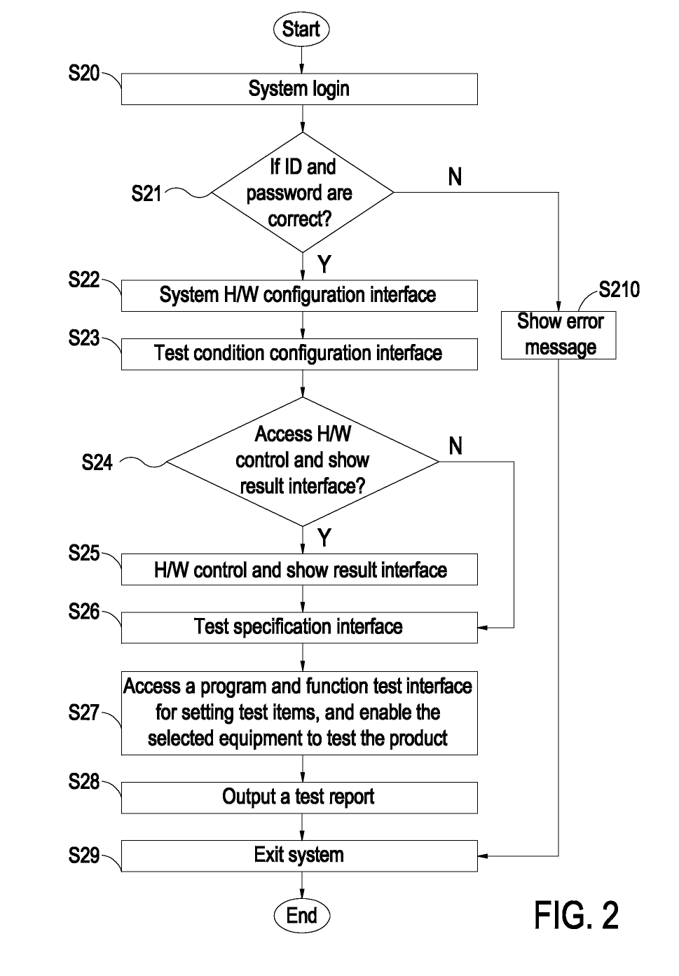

FIG. 2 is a flowchart illustrating an automatic testing method according to an embodiment of the present invention. Firstly, a system login process is performed through an electronic device 10 (Step S20), and thus a system login page appears (not shown). A user ID and a password can be inputted through the system login page. If the user ID and the password are correct, a system H/W configuration interface is accessed (Step S22). Through the system H/W configuration interface, at least one of the equipments of the equipment group 11 to be set and tested is selected. Whereas, if the user ID or the password is incorrect, an error message is shown (Step S210), and then the system is exited (Step S29).

After the selected equipment is set through the system H/W configuration interface (Step S22), a test condition configuration interface is generated (Step S23). Through the test condition configuration interface, different test conditions can be set by the user. For example, 50% loading may be selected as the test condition. After the test conditions are inputted, an H/W control and show result interface is optionally accessed according to the user's requirement (Step S24). If the H/W control and show result interface is accessed (Step S25), the parameters associated with the selected equipment can be set through the H/W control and show result interface. After the parameters of the selected equipment are set, the selected equipment is H/W controlled, and the output result of the selected equipment is shown. If the H/W control and show result interface is not accessed, the step S26 is performed to access a test specification interface. Through the test specification interface, the target specifications of the to-be-tested product can be set. After the testing process is completed, the test results of the product and the target specifications can be compared with each other to judge whether the product passes the test.

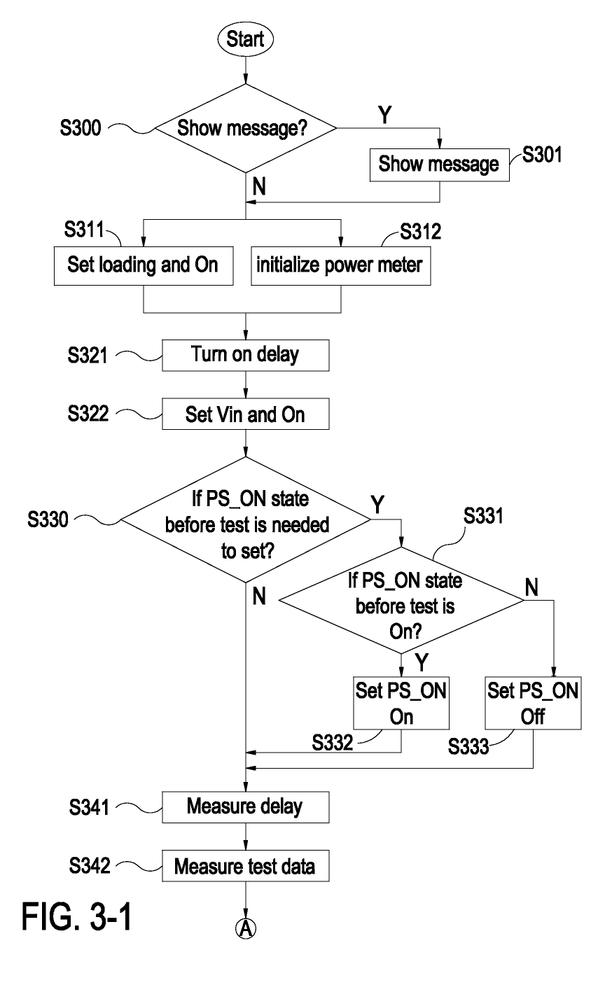

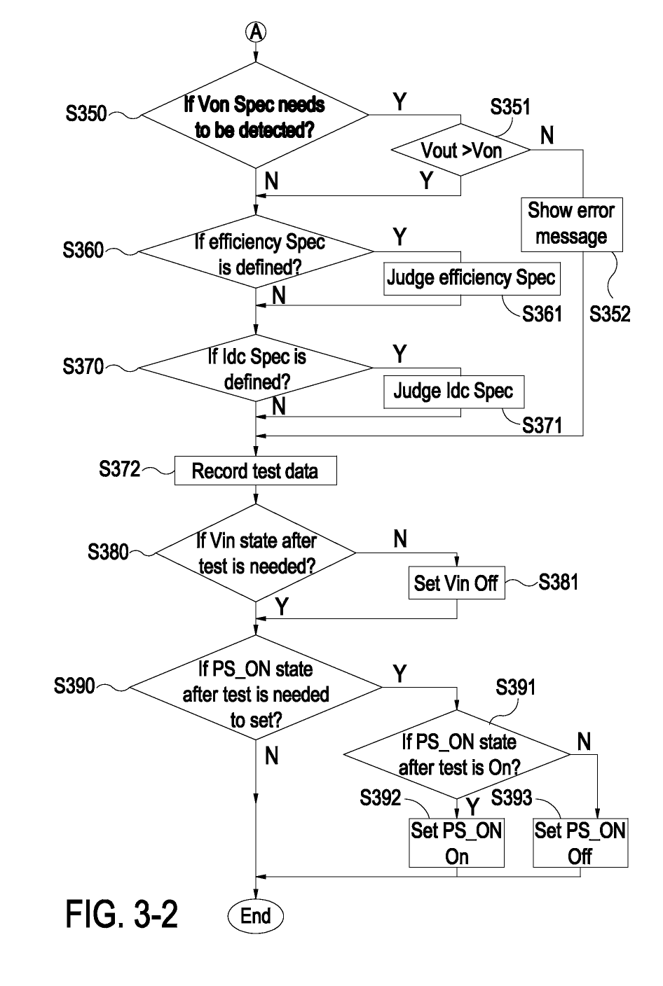

After the target specifications of the product are set, a program and function test interface is accessed. Through the program and function test interface, the test items are set. In addition, the selected equipment is enabled to test the product according to the above setting values (Step S27). Through the program and function test interface, different functions can be tested according to respective testing processes (see FIG. 3). In such way, different testing processes corresponding to different test items will be executed according to the practical requirements. After the executions of the testing processes are completed, the test result will be transmitted from the at least one equipment to the electronic device 10 through the integrated transmission interface 105. At the same time, a test report is outputted from the output unit 104 (Step S28). The test report is automatically outputted from the output unit 104 as a test sheet or a test chart. In addition, the test report can be stored or outputted according to the practical requirements. After the test report is shown or stored, the user can exit the testing system (Step S29). Meanwhile, the automatic testing method of the present invention is completed. That is, the automatic testing method of the present invention has both functions of controlling and testing the equipment group 11. After the parameters of the selected equipment are set, the equipment group 11 can be controlled and monitored. By executing the automatic testing collaborative program, the automatic testing process is performed and the test report is automatically shown on the electronic device 10. That is, the automatic testing system of the present invention has powerful automatic testing and monitoring functions.

FIGS. 3-1 and 3-2 are flowcharts illustrating an efficiency testing process applied to the automatic testing method of the present invention. After the associated settings of a product are made, an efficiency testing process will be performed. After the program and function test interface is accessed, the following steps will be carried out to test the efficiency of the product. Firstly, Step S300 is performed to determine whether a prompt message is shown. If the prompt message is needed, the prompt message is shown to guide the user how to operate the efficiency testing process (S301). Otherwise, Step S311 is performed to set loading and on, and Step S312 is performed to initialize a power meter. After Step S311 and Step S312 are performed, at least one equipment to be tested is loaded and a turn-on delaying action is enabled (Step S321). Consequently, the at least one equipment has sufficient response time. The time of the turn-on delaying action is several milliseconds (mS).

Then, the input voltage is set and turned on (Step S322). After the input voltage is turned on, Step S330 is performed to judge whether the DC state (PS_ON state) before test is needed to set. If the DC state before test is needed to set, Step S331 is performed to determine whether the DC state before test is on. If the condition of Step S331 is satisfied, the DC state is turned on (Step S332); or otherwise, the DC state is turned off (Step S333). If the DC state before test is not needed to set, the next step is performed to delay the measuring time (Step S341). Consequently, the steady state of the product is achieved. Similarly, the time of delaying the measuring action is several milliseconds (mS).

Then, the test data are measured to obtain associated data of the product (Step S342). If the user decides to detect the output voltage (Step S350), the output voltage (Vout) is detected and compared with a set value to judge whether the output voltage is higher than the set value (Von) (Step S351). If the test result indicates that the output voltage (Vout) is not higher than the set value (Von), an erroneous message is shown to indicate that the product is unqualified (Step S352) and the test data are recorded (Step S372). Whereas, if the test result indicates that the output voltage (Vout) is higher than the set value (Von) in Step S350, Step S360 is performed to judge whether the efficiency specification is defined, thereby realizing whether the input condition set by the user includes the efficiency test item. If the efficiency specification is defined, Step S361 is performed to evaluate the efficiency; or otherwise Step S370 is performed to judge whether Idc specification is defined. If the Idc specification is defined, Step S371 is performed to evaluate the Idc specification; or otherwise Step 372 is performed to record the test data. Meanwhile, the test data associated with the output voltage, the efficiency and the loading are recorded.

After the above items about the product are tested, the following settings are made. Then, Step S380 is performed to judge whether the Vin state after test is needed. If the Vin state after test is needed, Step S390 is performed to judge whether the DC state after the test needs to be turned on; or otherwise the input power (Vin) is turned off (Step S381). If the DC state after test is needed to set, Step S391 is performed to judge whether the DC state after the test is on. If the condition of Step S391 is satisfied, the DC is turned on (Step S392); or otherwise, the DC is turned off (Step S393). Meanwhile, the efficiency testing process of the product is completed.

The above descriptions of preferred embodiments are presented herein for purpose of illustration and description only. The testing items are not restricted. The above-mentioned efficiency testing process is automatically performed according to the selected conditions and parameters without the need of manually checking and outputting the test result. Moreover, the test report can be expressed as a test sheet or a test chart (e.g. a waveform chart or a trend chart), which are automatically created from a text file (e.g. a Microsoft Word file) or a spreadsheet (e.g. a Microsoft Excel file).

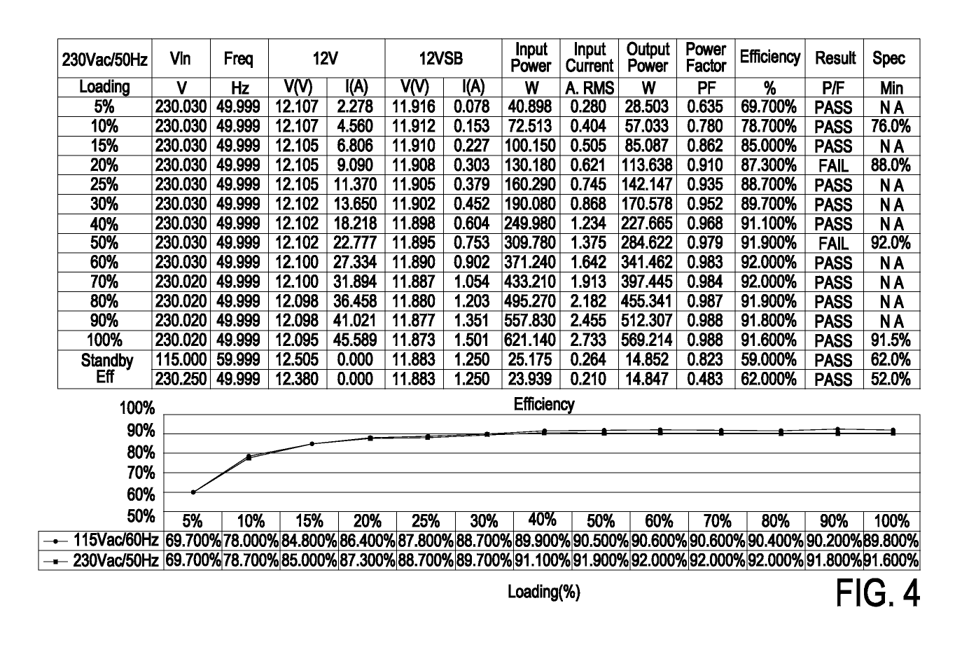

FIG. 4 is a schematic diagram illustrating a test report obtained according to the automatic testing method of the present invention. The test report indicates the measured values of the input power, the input current, the output power, the power factor and the efficiency at a constant input voltage (Vin), a constant frequency (Freq) and different loading conditions (5%, 10%, 15%, 20%, 25%, 30%, 40%, 50%, 60%, 70%, 80%, 90% and 100%). After the measured values are compared with predetermined reference values, the test result “PASS” indicates that the product is a qualified product able to pass the test, and the test result “FAIL” indicates that the product fails to pass the test. In such way, the user can obviously realize whether the test results comply with anticipated results. Moreover, since the test report can be expressed as a test sheet or a test chart (e.g. a waveform chart or a trend chart), the user or the customer can easily inquire about the test results and further verify the test results.

From the above description, the present invention provides an automatic testing system and an automatic testing method. The automatic testing system comprises an electronic device and an equipment group. The electronic device and the equipment group collaboratively communicate with each other. Through an integrated transmission interface, the electronic device controls at least one of the equipments of the equipment group to automatically test some items (e.g. voltage, power source, power, efficiency or loading) of the product. After the automatic testing process is completed, the test result is outputted as a test report, which is expressed as a test sheet or a test chart. In other words, in the automatic testing system and the automatic testing method of the present invention, the electronic device can directly control the equipment group to automatically monitor, control and test the product. Moreover, in a case that high precision testing equipments of the equipment group are included in the automatic testing system, the precision of the automatic testing method of the present invention will be enhanced without the need of purchasing an additional testing instrument.

Moreover, the automatic testing method of the present invention can be implemented through an electronic device. The operating interface is easy-to-use for different users. Since the steps of manually collecting and analyzing the test data are omitted according to the present invention, the automatic testing method of the present invention is automatic, time-saving, precise, cost-effective, efficient and collaborative.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An automatic testing system, comprising:
an equipment group comprising plural equipments; and
an electronic device comprising:
an input unit for inputting an instruction;
a storage unit;
a controller electrically connected with said input unit and said storage unit for accessing said storage unit according to said instruction, thereby controlling and activating an automatic testing process and issuing a test command;
an output unit connected with said controller; and
an interface having a first terminal connected with said controller and a second terminal connected with said equipment group for integrating and transmitting said test command to at least one of said equipments of said equipment group.

2. The automatic testing system according to claim 1, wherein a test result is transmitted from said equipment group to said controller, wherein said test result is calculated and collected by the controller, thereby outputting a test report.

3. The automatic testing system according to claim 2, wherein said test report is automatically outputted as selected a group of a test sheet, a test chart and a combination thereof.

4. The automatic testing system according to claim 1, wherein said equipment group comprises a condition equipment sub-group, which comprises selected a group of an AC source, an electronic load and a signal multiplexer.

5. The automatic testing system according to claim 1, wherein said equipment group comprises a test equipment sub-group, which comprises selected a group of an oscilloscope, a multi meter and a power meter.

6. The automatic testing system according to claim 1, wherein said electronic device is a computer system.

7. The automatic testing system according to claim 1, wherein said electronic device is a PXI (PCI eXtensions for Instrumentation).

8. The automatic testing system according to claim 1, wherein said input unit is selected a group of a keyboard and a mouse, said controller is a central processing unit, and said output unit is selected a group of a monitor and a printing device.

9. The automatic testing system according to claim 1, wherein said interface is a GPIB (general purpose interface bus) interface.

10. The automatic testing system according to claim 1, wherein said automatic testing is performed by executing an automatic testing collaborative program, which is written in a graphic editing language (LabVIEW).

11. An automatic testing method, comprising:
providing an automatic testing system including a system H/W configuration interface, a test condition configuration interface and a H/W control and show result interface;
selecting at least one of plural equipments of an equipment group through said system H/W configuration interface;
setting a test condition through said test condition configuration interface;
optionally accessing said H/W control and show result interface;
setting parameters associated with said selected equipment through said H/W control and show result interface when said H/W control and show result interface is accessed;
accessing a test specification interface and setting a target specification of a to-be-tested product through said test specification interface when said H/W control and show result interface isn't accessed;
accessing a program and function test interface and enabling said selected equipment to test said to-be-tested product according to plural setting values through said program and function test interface; and
outputting a test report.

12. The automatic testing method according to claim 11, further comprising a step of performing a system login process, thereby checking whether a user ID and a password are correct.

13. The automatic testing method according to claim 12, wherein if said user ID or said password is incorrect, an error message is shown and a system exit step is performed.

14. The automatic testing method according to claim 11, wherein said equipment group comprises a condition equipment sub-group, which comprises selected a group of an AC source, an electronic load and a signal multiplexer.

15. The automatic testing method according to claim 11, wherein said equipment group comprises a test equipment sub-group, which comprises selected a group of an oscilloscope, a multi meter and a power meter.

16. The automatic testing method according to claim 11, wherein after said parameters of said selected equipment are set through said through said H/W control and show result interface, said selected equipment is H/W controlled, and an output result of said selected equipment is shown.

17. The automatic testing method according to claim 11, further comprising a step of selecting different functions to be tested through said program and function test interface.

18. The automatic testing method according to claim 11, wherein said test report is automatically outputted and stored as selected a group of a test sheet, a test chart and a combination thereof.
